(19) United States
(12) Patent Application Publication
(10) Pub. No.: US 2009/0184613 A1
(43) Pub. Date: Jul. 23, 2009

(54) Space Saving Case For Computer Components

(76) Inventors: Enrico Barina, Venice (IT); Renzo Croatto, Venice (IT); Roberto Scarpa, Venice (IT)

Correspondence Address: BOYLE FREDRICKSON S.C., 840 North Plankinton Avenue, MILWAUKEE, WI, 53203, US

(21) Appl. No.: 12/016,023

(22) Filed: Jan. 17, 2008

(51) Int. Cl. A47B 88/00; H05K 5/00; A47B 81/00

(52) U.S. Cl. 312/334.23; 312/223.2; 312/330.1

(57) ABSTRACT

Metallic case by two unit composed made for lodge hardware components with aim complete assembly of PC. The first section is the mainboard location while, the second one contain other removable unit and the starter command.

Both of the case can be assembled on office furniture like desk, table ect . . . is possible put combined or separate.

### BACKGROUND OF THE INVENTION

1. Field of the Invention

The present invention relates to an improved computer case fixed on a desktop of a desk or of a table, and to the piece of office furniture comprising that.

2. Background of the Invention

In the IT (Information Technology) field, specifically in technical assistance, the skilled persons are well aware of the existence of several disadvantages connected to the PC cases available on the market.

The structure of a PC case is typically a standard shape, and the differences among various models consist almost solely in the design of the front panel.

One of the most common problem concerns in a PC is its internal hygiene: the fan's flow, in both directions, brings quite a large amount of dust and impurities inside the case, often causing an incorrect working of all the delicate components. This mostly happens in schools, universities and office environments, where there's no particular care in daily cleanings.

The location of the PC case is another common problem: although being comfortable over a desktop or a worktop, it takes up a lot of useful space. If placed on the floor it is not so easily accessible and dust can become a serious concern, causing overheating that may compromise the PC's components life.

Various assemblies of computers are known in order to make maximum use of the space available, For example, EP 1462027 discloses a PC housed in an overhead panel, with connectors for data cables, and suspended over an operator's desk. The desk has a flat horizontal top to hold paperwork and a horizontal ledge at the front to hold the keyboard and the mouse. The computer monitor is mounted on the far side of the table top. Nevertheless this solution requires the use of a suspended panel above the head of the operator which cannot be easily accessed and cleaned. In addition, it is quite bulky and complex in its installation. Also, GB 2344741 describes a drawer type computer mounting system that includes a housing formed of a bottom shell, a top cover shell, a face panel, and two slide rails fastened to opposite vertical side panels of the bottom shell for permitting it to be moved between two slide tracks in a desk. While this solution improves the easiness of the installation of the case it cannot be used in an existing desk and does not help in the maintenance of the PC. In addition it does provide an optimal exploitation of the available space.

Finally, the European patent application EP 1 825 777 A1 from the same applicants offers a valuable solution providing a computer case comprising two separated box shaped elements connected therebetween, containing different components of a PC, and fixed underneath a desktop with guides, so as to allow the box shaped elements to slide as a drawer.

Although this solution is advantageous in offering a good exploitation of space, it can be improved in its design, in particular for the sake of an easier and more effective manufacturing.

Hence, the technical problem underlying the present invention is to provide a computer case apt to be placed in a position allowing to overcome the drawbacks mentioned above with reference to the known art.

### SUMMARY OF THE INVENTION

The afore-mentioned problems are solved by a computer case comprising a first unit and a second unit, the first unit housing internal peripherals and comprising a front panel with power switches and the second unit comprising a main box housing a power supply unit and a motherboard, said front panel and main box being separated by means of dividing panel, the computer case further comprising a single lid closing both the main box and the front panel, said lid comprising guides that can be fixed below a desktop of a piece of furniture so as to allow the whole structure to be pulled out like a drawer.

Moreover the invention is also directed to a piece of furniture comprising a computer case fixed underneath a desktop, said computer case comprising a first unit and a second unit, the first unit housing internal peripherals and comprising a front panel with power switches and the second unit comprising a main box housing a power supply unit and a motherboard, said front panel and main box being separated by means of dividing a panel, the computer case further comprising a single lid closing both the main box and the front panel, said lid comprising guides fixed below the desktop so as to allow the whole computer case to be pulled out like a drawer.

The case is formed by two metallic units made for lodging hardware components with the aim of a complete assembling of PCs. In the first unit is located the mainboard and the power supply unit while, the second unit contains other removable units and a starter command.

The case can be assembled on office furniture like a desk, table, etc., although it may be either combined or separate.

More precisely, the invention's subject consists of the application of the Personal Computer under the desktop or worktop of office desks, tables etc . . . In that way it is possible to make optimal use of unemployed spaces and to keep a work station and equipment clean.

Also, among other advantages this case, which can contain standard components, allows to avoid further costs.

Over a six-month test, no substantial failures occurred in the case.

The case according to the present invention avoids the use of high-miniaturized elements which are too expensive, delicate and less durable for daily use.

The production of our case does not entail any troubles because it can produced with laser technology allowing extreme precision in sheet-steel cutting. The folding, without use of a curling-die, can be obtained by laser-cut bi-dimensional moulds which are started by oleodynamic low-pressure jacks, in order to preserve the sheet-steel integrity.

All the parts can be joined by electric pressing or by rivets, but we avoided this in order to guarantee a total and easy disassembling of parts for maintenance, cleaning etc.

### DESCRIPTION OF THE DRAWINGS

FIG. 1 is an axonometric view of the complete cover unit, closed, equipped with standard 5.25″, slot, 3.5″ slot, fan, power supplies, input and output for fast peripheral, USB connectors, arranged for future connections.

FIG. 2 is an exploded view of the structural components of the cover unit.

FIG. 3 is an exploded view of the inner removable components for the maintenance end fixing of the elements of the PC: mainboard, 3.5″ unit, 5.25″ unit, switches, additional cards etc . . .

FIG. 4 is a plan view of Section A.

FIG. 5 is a schematic section showing the components as in FIG. 1, and the locking device of removable parts.

FIG. 6 is an enlarged view of the assembled components.

FIG. 7 is an enlarged view of the rear closing of the lid.

FIG. 8 is an enlarged view of the fixing system under the worktop (right side).

FIG. 9 is a plan view of Section B.

FIG. 10 is a schematic section of the switches box, lights and locking device.

FIG. 11 is a plan view of Section C.

FIG. 12 is a schematic section of the plugging area of side additional connections, and the plastic external panel.

### DETAILED DESCRIPTION OF THE INVENTION

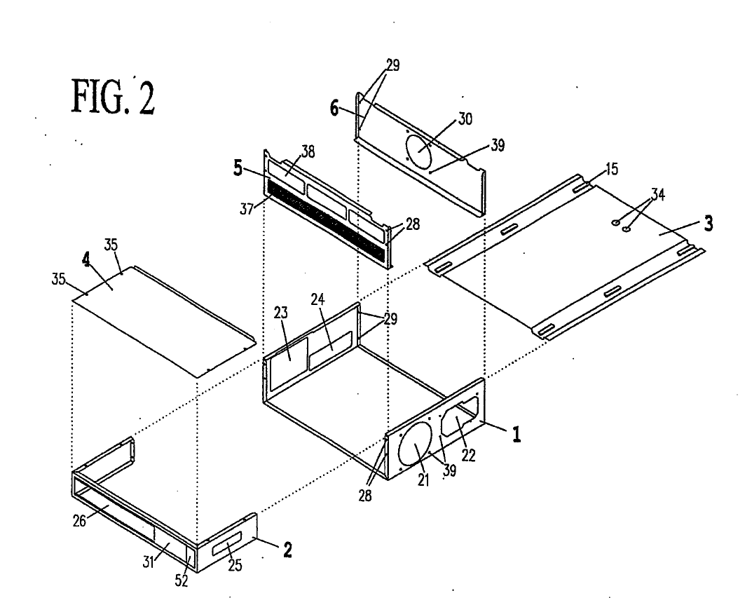

In FIG. 2 the main box 1 comes with four standard size openings, like all PC cabinets: a slot 21 for fan 120×120 mm, with fixing holes 39, opening 22 for power supplies with fixing holes, slots 23, 24 for external peripherals plugging.

Screws 28 for sealing of a front panel 2 and of a diving panel 5.

Threading holes 29 for fixing screws to part 6.

The front panel 2 is arranged with a single slot to host, with internal fixing, the standard internal peripherals: two 5.25″ slots 26, two 3.5″ slots 31, switches and lights 52.

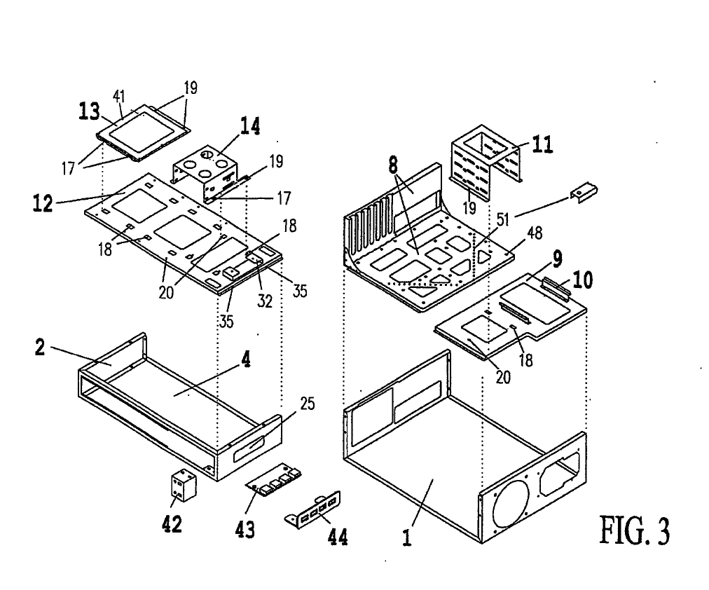

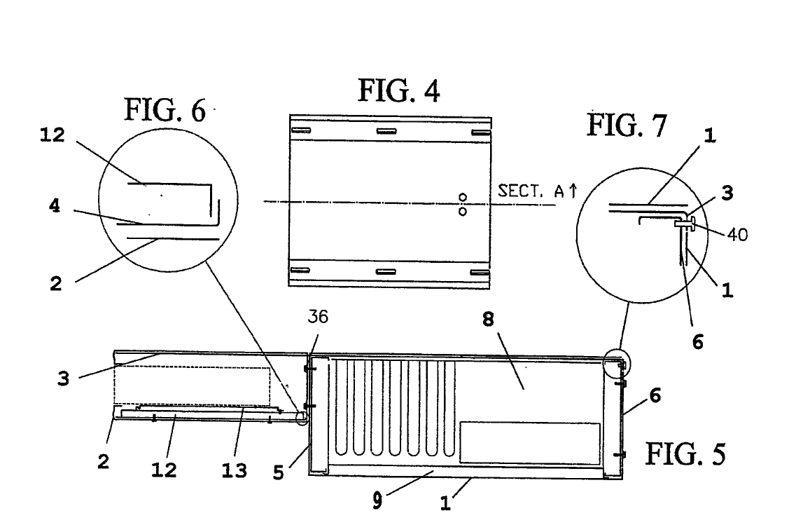

As shown in FIG. 12, in the slot 25 there is a card 43, for quick access connections. This card 43, is screwed on the brackets 32 by means of screws 45, as shown in FIG. 3 and FIG. 12. This card is available in a variety of choices.

As shown in FIG. 3, the bottom part 4 and part 12 are both screwed under the front panel 2, as appears in FIG. 5, with detail in FIG. 6.

With reference to FIG. 2, the dividing panel 5, is placed between the main box 1 and the front panel 2, and fixed by screws 36, shown in FIG. 5, through the screws holes 28.

The grid 37 contains a dust-proof, replaceable filter.

The slots 38 allows to place flat cables for connecting internal peripherals 26, 31 and switches and lights 42 to the mainboard and to the power supplies unit in the main box 1.

The rear panel 96 hosts a slot 30 for a fan (80×80 mm or 90×90 mm), and screw holes 39 for fan fixing.

Another central screw 40, shown in FIG. 7, allows to fix the lid 3 to the rear panel 6.

The internal removable components, for replacement and maintenance are illustrated in FIG. 3.

A component 8 holds the mainboard, and additional compatible cards. The component 8 is also supplied with two strengthening elements 51 fixed below by rivets along dotted lines, so as to avoid any bending of the component, damaging the mainboard. The screw holes 48 allow the fixing of most popular mainboards on the market.

The component 9 comes with two supports 10 for screwing of standard power supplies 39, shown in FIG. 2.

The tongues 18 and the threaded hole 20 allow a box fitting 11, by a screw through a hole 19.

The box 11 can contain three 3.5″ internal units.

On the front panel 2 there is the base 12 fixed on component 4, as displayed in FIG. 6. The base 12 can host two components 13, fixed by screws, through holes 19. Each component 13 allows the fixing of one 5.25″ unit, by means of screws through standard holes 41. Eventually, the tongues 18 of the component 12 are inserted in the openings 17 of parts 13, 14, by means of screws through holes 19 in the screw-cuttings 20.

The component 14 supports two 3.5″ units.

The section of FIG. 5 shows the outcome of groove-and-tongue joint of the components 1, 8, 9, 5 and 6.

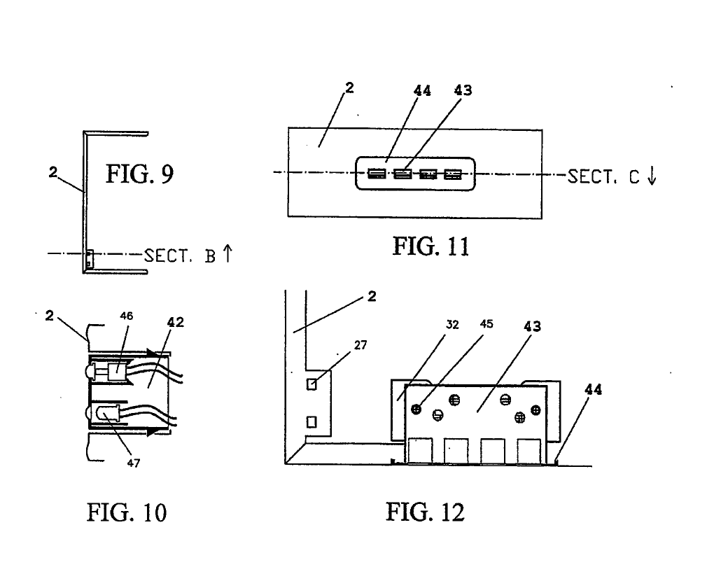

In FIG. 10, the switches and lights panel 42 are joined inside holes 27, which holes are made on two tongues obtained on the front panel 2, as specified on the schematic section of FIG. 10, and on the Section “B” of the plan view of FIG. 9.

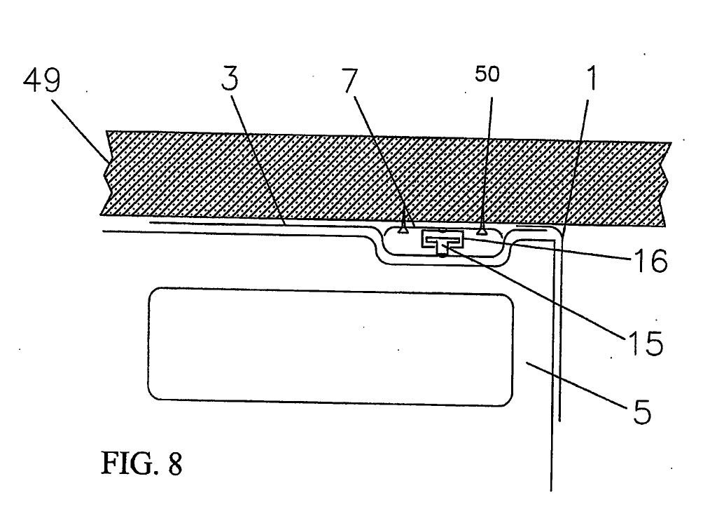

FIG. 8 highlights the fixing system on the whole structure under the worktop.

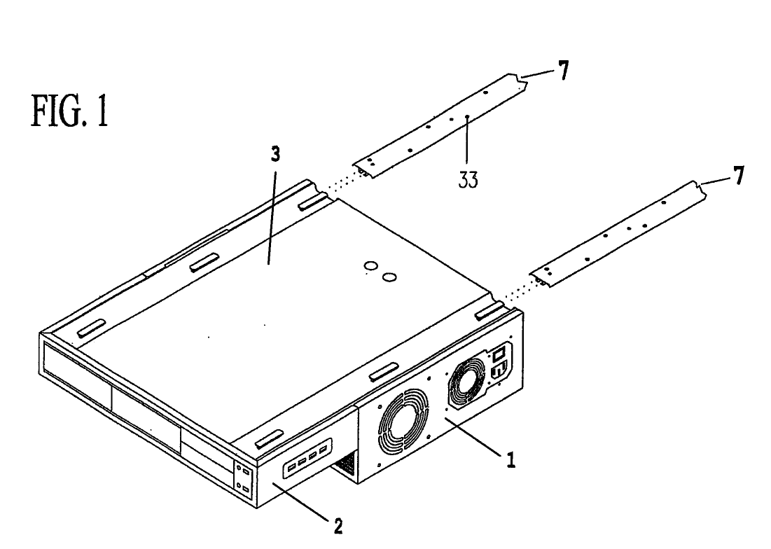

The two tracks 7, as seen in FIG. 1, are fixed under the worktop by screws 50 through holes 33. The guides 16 are fixed on tracks 7 with a C-shaped profile. The pins 15 run through the tracks 7, and are fixed to the lid 3. The lid 3 holds the whole structure, as displayed in FIG. 1.

The whole structure can be pulled out just like a drawer. The components 1 and 2 can be separately reversed, to meet the environmental needs where the case will be mounted.

Reversibility of component 2 is obtained by twisting it around 180° on plan and by twisting the component 12 180° on base plane.

Reversibility of component 1 is obtained by turning it around 180° on base plane.

1. (canceled)

2. A computer case comprising a first unit and a second unit, the first unit housing internal peripherals and comprising a front panel with power switches and the second unit comprising a main box housing a power supply unit and a motherboard, said front panel and main box being separated by means of dividing panel, the computer case further comprising a single lid closing both the main box and the front panel, said lid comprising guides that can be fixed below a desktop of a piece of furniture so as to allow the whole structure to be pulled out like a drawer.

3. The computer case according to claim 2, wherein said guides are coupled with tracks with a C-shaped profile fixed to said lid.

4. The computer case according to claim 2, wherein said dividing panel comprises a grid housing a filter.

5. The computer case according to claim 2, wherein said filter is replaceable.

6. The computer case according to claim 2, wherein said main box comprises a component for holding the mainboard, and additional compatible cards.

7. The computer case according to claim 6, wherein said component is provided with two strengthening elements fixed therebelow.

8. The computer case according to claim 2, wherein said main box comprises a component for holding standard power supplies.

9. The computer case according to claim 2, wherein said first unit comprises a bottom part and a base fixed thereon.

10. The computer case according to claim 2, wherein said guides are fixed on said lid.

11. A piece of furniture comprising a computer case fixed underneath a top, said computer case comprising a first unit and a second unit, the first unit housing internal peripherals and comprising a front panel with power switches and the second unit comprising a main box housing a power supply unit and a motherboard, said front panel and main box being separated by means of dividing panel, the computer case further comprising a single lid closing both the main box and the front panel, said lid comprising guides fixed below the desktop so as to allow the whole computer case to be pulled out like a drawer.

12. The piece of furniture according to claim 11, wherein said guides are coupled with tracks with a C-shaped profile fixed to said lid.

13. The piece of furniture according to claim 11, wherein said dividing panel comprises a grid housing a filter.

14. The piece of furniture according to claim 13, wherein said filter is replaceable.

15. The piece of furniture according to claim 11, wherein said main box comprises a component for holding the mainboard, and additional compatible cards.

16. The piece of furniture according to claim 15, wherein said component is provided with two strengthening elements fixed therebelow.

17. The piece of furniture according to claim 11, wherein said main box comprises a component for holding standard power supplies.

18. The piece of furniture according to claim 11, wherein said first unit comprises a bottom part and a base fixed thereon.

19. The piece of furniture according to claim 11, wherein said guides are fixed on said lid.
